(19) United States
(12) Patent Application Publication
(10) Pub. No.: US 2025/0294744 A1
(43) Pub. Date: Sep. 18, 2025

(54) MEMORY DEVICE AND METHOD OF MANUFACTURING THE MEMORY DEVICE

(71) Applicant: SK hynix Inc., Icheon-si Gyeonggi-do (KR)

(72) Inventors: Do Young KIM, Icheon-si Gyeonggi-do (KR); Eun Mee KWON, Icheon-si Gyeonggi-do (KR)

(73) Assignee: SK hynix Inc., Icheon-si Gyeonggi-do (KR)

(21) Appl. No.: 18/790,488

(22) Filed: Jul. 31, 2024

(30) Foreign Application Priority Data
Mar. 13, 2024 (KR) 10-2024-0035213

(51) Int. Cl. H10B 43/27; H10B 43/10

(52) U.S. Cl. CPC H10B 43/27; H10B 43/10

(57) ABSTRACT

Provided herein is a memory device and a method of manufacturing the memory device. The memory device includes a channel layer extending in a first direction, a tunnel isolation layer extending in the first direction and surrounding the channel layer, a first charge trap layer surrounding a portion of the tunnel isolation layer, a second charge trap layer surrounding the first charge trap layer, and a blocking layer surrounding the second charge trap layer, wherein the second charge trap layer is configured to trap more charges than the first charge trap layer.

### CROSS-REFERENCE TO RELATED APPLICATION

The present application claims priority under 35 U.S.C. § 119(a) to Korean patent application number 10-2024-0035213 filed on Mar. 13, 2024, in the Korean Intellectual Property Office, the entire contents of which application is incorporated herein by reference.

### BACKGROUND

### 1. Technical Field

Various embodiments of the present disclosure generally relate to a memory device and a method of manufacturing the memory device, and more particularly to a memory device having a three-dimensional (3D) structure and a method of manufacturing the memory device.

### 2. Related Art

A memory device may include a memory cell array in which data is stored, and a peripheral circuit which is configured to perform a program operation, a read operation or an erase operation on the memory cell array.

The memory cell array may include memory blocks, and each of the memory blocks may be formed in a two-dimensional (2D) or three-dimensional (3D) structure.

Each memory block formed in a 2D structure may include memory cells arranged along a substrate. Each memory block formed in a 3D structure may include memory cells stacked on a substrate in a vertical direction. The memory cells in the memory block formed in the 3D structure may be programmed by trapping charges in a charge trap layer.

In a typical memory device having a 3D structure, the charge trap layer may extend in a vertical direction. Because different memory cells trap charges in different regions of the charge trap layer extending in a vertical direction, an interference may increase between memory cells adjacent to each other in a vertical direction, and retention characteristics in that threshold voltages of programmed memory cells need to be maintained may be deteriorated.

### SUMMARY

An embodiment of the present disclosure may provide for a memory device. The memory device may include a channel layer extending in a first direction, a tunnel isolation layer extending in the first direction and surrounding the channel layer, a first charge trap layer surrounding a portion of the tunnel isolation layer, a second charge trap layer surrounding the first charge trap layer, and a blocking layer surrounding the second charge trap layer, wherein the second charge trap layer is configured to trap more charges than the first charge trap layer.

An embodiment of the present disclosure may provide for a memory device. The memory device may include a channel layer including an uneven structure and extending in a vertical direction, a tunnel isolation layer including the uneven structure and surrounding the channel layer, a first charge trap layer disposed in a depressed portion of the tunnel isolation layer, a blocking layer surrounding the first charge trap layer, a second charge trap layer contacting a top of the blocking layer; and, and a third charge trap layer contacting a bottom of the blocking layer.

An embodiment of the present disclosure may provide for a method of manufacturing a memory device. The method may include alternately stacking material layers and first sacrificial layers, forming a vertical hole in the material layers and the first sacrificial layers that are stacked, forming first recesses by removing portions of the first sacrificial layers exposed through the vertical hole, forming second sacrificial layers in the first recesses, forming second recesses by removing portions of the material layers exposed through the vertical hole, forming a first charge trap layer, a tunnel isolation layer, and a channel layer in the vertical hole, removing the first and second sacrificial layers; separating the first charge trap layer into a second charge trap layer that remains in a region from which the second sacrificial layers are removed, and third charge trap layers that contact the material layers, by partially removing a bent portion of the first charge trap layer, forming a fourth charge trap layer in a region surrounded by the first to third charge trap layers, and forming a blocking layer surrounding the fourth charge trap layer.

An embodiment of the present disclosure may provide for a method of manufacturing a memory device. The method may include alternately stacking material layers and first sacrificial layers, forming a vertical hole in the material layers and the first sacrificial layers that are stacked, forming first recesses by removing portions of the first sacrificial layers exposed through the vertical hole, forming second sacrificial layers in the first recesses, forming second recesses by removing portions of the material layers exposed through the vertical hole, forming a first charge trap layer, a tunnel isolation layer, and a channel layer in the vertical hole, removing the first and second sacrificial layers, separating the first charge trap layer into a second charge trap layer that remains in a region from which the second sacrificial layers are removed, and third charge trap layers that contact the material layers, by partially removing a bent portion of the first charge trap layer, and forming a blocking layer in a region surrounded by the first to third charge trap layers.

An embodiment of the present disclosure may provide for a method of manufacturing a memory device. The method may include alternately stacking material layers and sacrificial layers, forming a vertical hole in the material layers and the sacrificial layers that are stacked, forming first recesses by removing portions of the sacrificial layers exposed through the vertical hole, forming a first charge trap layer, a tunnel isolation layer, and a channel layer, each having an uneven structure, in the vertical hole including the first recesses, removing a portion of the sacrificial layer such that a portion of the sacrificial layer remains in a depressed portion of the first charge trap layer having the uneven structure, and forming a blocking layer that separates the first charge trap layer into a second charge trap layer and a third charge trap layer by oxidizing the remaining sacrificial layer.

### BRIEF DESCRIPTION OF THE DRAWINGS

FIG. 1 is a diagram illustrating a memory device according to an embodiment of the present disclosure.

FIG. 2 is a diagram illustrating a memory block according to an embodiment of the present disclosure.

FIGS. 3A and 3B are views illustrating the structure of memory devices according to first embodiments of the present disclosure.

FIGS. 4A, 4B, 4C, 4D, 4E, 4F, 4G, 4H, 4I, 4J, and 4K are views illustrating a method of manufacturing the memory devices according to the first embodiments of the present disclosure.

FIG. 5 is a view illustrating the structure of memory devices according to second embodiments of the present disclosure.

FIGS. 6A and 6B are views illustrating a method of manufacturing the memory devices according to the second embodiments of the present disclosure.

FIG. 7 is a view illustrating the structure of memory devices according to third embodiments of the present disclosure.

FIGS. 8A, 8B, 8C, 8D, and 8E are views illustrating a method of manufacturing the memory devices according to the third embodiments of the present disclosure.

FIG. 9 is a diagram illustrating a solid state drive (SSD) system to which a memory device according to an embodiment the present disclosure is applied.

FIG. 10 is a diagram illustrating a memory card system to which a memory device according to an embodiment the present disclosure is applied.

### DETAILED DESCRIPTION

Specific structural or functional descriptions, disclosed herein, are exemplified to describe embodiments according to the concepts of the present disclosure. The embodiments according to the concepts of the present disclosure should not be construed as being limited to embodiments described below, and may be modified in various forms and replaced with other equivalent embodiments.

Hereinafter, it will be understood that, although the terms “first” and “second” may be used herein to describe various elements, these elements should not be limited by these terms. The terms are used to distinguish one element from other elements.

Various embodiments of the present disclosure are directed to a memory device and a method of manufacturing the memory device, which can improve the retention characteristics of memory cells.

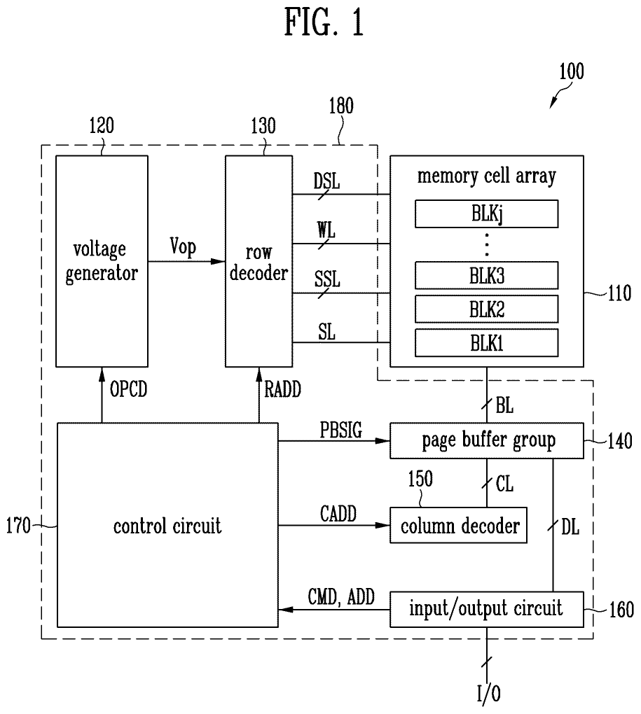

FIG. 1 is a diagram illustrating a memory device according to an embodiment of the present disclosure.

Referring to FIG. 1, a memory device 100 may include a memory cell array 110 and a peripheral circuit 180.

The memory cell array 110 may include first to j-th memory blocks BLK1 to BLKj. Each of the first to j-th memory blocks BLK1 to BLKj may include memory cells capable of storing data. Drain select lines DSL, word lines WL, source select lines SSL, and a source line SL may be coupled to each of the first to j-th memory blocks BLK1 to BLKj, and bit lines BL may be coupled in common to the first to j-th memory blocks BLK1 to BLKj.

Each of the first to j-th memory blocks BLK1 to BLKj may be formed to have a two-dimensional (2D) structure or a three-dimensional (3D) structure. Each memory block having a 2D structure may include memory cells arranged in parallel on a substrate. Each memory block having a 3D structure may include memory cells stacked on a substrate in a vertical direction. In the present embodiment, each memory block formed to have the 3D structure is disclosed as an embodiment.

According to a program scheme, each memory cell may store 1 bit of data or 2 or more bits of data. For example, a scheme for storing 1 bit of data in one memory cell is referred to as a single-level cell (SLC) scheme, and a scheme for storing 2 bits of data in one memory cell is referred to as a multi-level cell (MLC) scheme. A scheme for storing 3 bits of data in one memory cell is referred to as a triple-level cell (TLC) scheme, and a scheme for storing 4 bits of data in one memory cell is referred to as a quad-level cell (QLC) scheme. In addition, 5 or more bits of data may be stored in one memory cell.

The peripheral circuit 180 may perform a program operation of storing data in the memory cell array 110, a read operation of outputting data stored in the memory cell array 110, and an erase operation of erasing data stored in the memory cell array 110. For example, the peripheral circuit 180 may include a voltage generator 120, a row decoder 130, a page buffer group 140, a column decoder 150, an input/output circuit 160, and a control circuit 170.

The voltage generator 120 may generate various operating voltages Vop that are used for a program operation, a read operation, or an erase operation in response to an operation code OPCD. For example, the voltage generator 120 may generate program voltages, turn-on voltages, turn-off voltages, negative voltages, precharge voltages, verify voltages, read voltages, pass voltages, or erase voltages in response to the operation code OPCD. The operating voltages Vop generated by the voltage generator 120 may be applied to the drain select lines DSL, the word lines WL, the source select lines SSL, and the source line SL of a memory block selected through the row decoder 130.

The program voltages may be voltages that are applied to the selected word line among the word lines WL during a program operation, and may be used to increase the threshold voltages of memory cells coupled to the selected word line. The turn-on voltages may be applied to the drain select lines DSL or the source select lines SSL, and may be used to turn on drain select transistors or source select transistors. The turn-off voltages may be applied to the drain select lines DSL or the source select lines SSL, and may be used to turn off the drain select transistors or the source select transistors. For example, the turn-off voltages may be set to 0 V. The precharge voltages may be voltages higher than 0 V, and may be applied to the bit lines during a read operation. The verify voltages may be used during a verify operation of determining whether the threshold voltages of selected memory cells have increased to a target level. The verify voltages may be set to various levels according to the target level, and may be applied to the selected word line.

The read voltages may be applied to the selected word line during a read operation performed on the selected memory cells. For example, the read voltages may be set to various levels according to the program scheme for the selected memory cells. The pass voltages may be voltages that are applied to unselected word lines among the word lines WL during a program or read operation, and may be used to turn on memory cells coupled to the unselected word lines.

The erase voltages may be used during an erase operation of erasing the memory cells included in the selected memory block, and may be applied to the source line SL.

The row decoder 130 may transmit the operating voltages Vop to the drain select lines DSL, the word lines WL, the source select lines SSL, and the source line SL, which are coupled to a memory block selected according to a row address RADD. For example, the row decoder 130 may be coupled to the voltage generator 120 through global lines GL, and may be coupled to the first to j-th memory blocks BLK1 to BLKj through the drain select lines DSL, the word lines WL, the source select lines SSL, and the source line SL.

The page buffer group 140 may include page buffers (not illustrated) coupled to the first to j-th memory blocks BLK1 to BLKj, respectively. The page buffers (not illustrated) may be coupled to the first to j-th memory blocks BLK1 to BLKj, respectively, through the bit lines BL. During a read operation, the page buffers (not illustrated) may sense the currents or voltages of the bit lines varying with the threshold voltages of the selected memory cells in response to page buffer control signals PBSIG, and may, for a definite duration, store the sensed data.

The column decoder 150 may be configured such that data is transferred between the page buffer group 140 and the input/output circuit 160 in response to a column address CADD. For example, the column decoder 150 may be coupled to the page buffer group 140 through column lines CL, and may transmit enable signals through the column lines CL. The page buffers (not illustrated) included in the page buffer group 140 may receive or output data through data lines DL in response to the enable signals.

The input/output circuit 160 may receive or output a command CMD, an address ADD, or data through input/output lines I/O. For example, the input/output circuit 160 may transmit the command CMD and the address ADD, received from an external controller through the input/output lines I/O, to the control circuit 170, and may transmit the data, received from the external controller through the input/output lines I/O, to the page buffer group 140. Alternatively, the input/output circuit 160 may output data, received from the page buffer group 140, to the external controller through the input/output lines I/O.

The control circuit 170 may output the operation code OPCD, the row address RADD, the page buffer control signals PBSIG, and the column address CADD in response to the command CMD and the address ADD. For example, when the command CMD input to the control circuit 170 is a command corresponding to a program operation, the control circuit 170 may control the devices included in the peripheral circuit 180 so that the program operation is performed on a memory block selected by the address ADD. When the command CMD input to the control circuit 170 is a command corresponding to a read operation, the control circuit 170 may control the devices included in the peripheral circuit 180 so that the read operation is performed on a memory block selected by the address and read data is output. When the command CMD input to the control circuit 170 is a command corresponding to an erase operation, the control circuit 170 may control the devices included in the peripheral circuit 180 so that the erase operation is performed on a selected memory block.

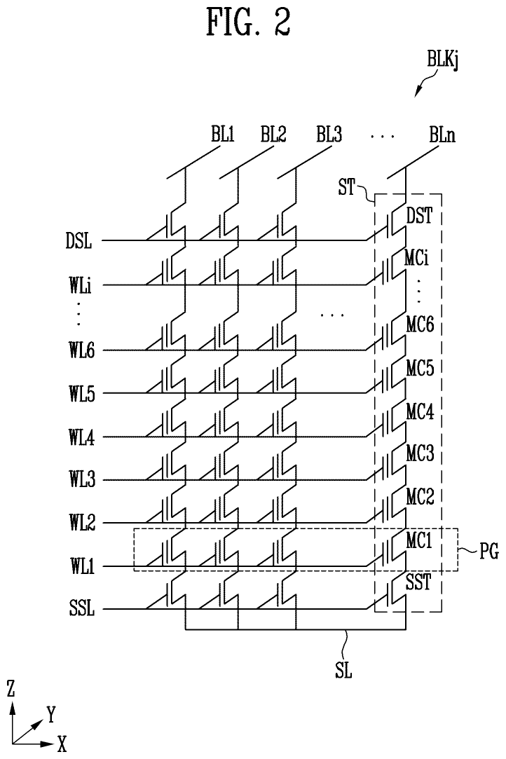

FIG. 2 is a diagram illustrating a memory block according to an embodiment of the present disclosure.

Because the first to j-th memory blocks BLK1 to BLKj illustrated in FIG. 1 may be configured in the same manner, the j-th memory block BLKj among the first to j-th memory blocks BLK1 to BLKj is illustrated as an example.

Referring to FIG. 2, the j-th memory block BLKj may include strings ST coupled between first to n-th bit lines BL1 to BLn and a source line SL. Because the first to n-th bit lines BL1 to BLn extend along a Y direction and are arranged to be spaced apart from each other along an X direction, the strings ST extending along a Z direction may be arranged to be spaced apart from each other along the X and Y directions. In FIG. 2, the strings ST arranged in the X direction are illustrated.

When any one string ST among the strings ST coupled to the n-th bit line BLn is described by way of example, the string ST may include a source select transistor SST, first to i-th memory cells MC1 to MCi, and a drain select transistor DST. Because the j-th memory block BLKj illustrated in FIG. 2 schematically explains the connection configuration of the memory block, the numbers of source select transistors SST, first to i-th memory cells MC1 to MCi, and drain select transistors DST included in each of the strings ST may vary depending on the memory device.

Gates of source select transistors SST included in different strings ST may be coupled to a source select line SSL, gates of the first to i-th memory cells MC1 to MCi may be coupled to first to i-th word lines WL1 to WLi, and gates of drain select transistors DST may be coupled to a drain select line DSL.

Memory cells formed on the same layer among the first to i-th memory cells MC1 to MCi may be coupled to the same word line. For example, the first memory cells MC1 included in different strings ST may be coupled in common to the first word line WL1, and the i-th memory cells MCi included in different strings ST may be coupled in common to the i-th word line WLi. A group of memory cells included in different strings ST and coupled to the same word line may be a page (PG). The program and read operations may be performed on a page (PG) basis, and the erase operation may be performed on a memory block basis.

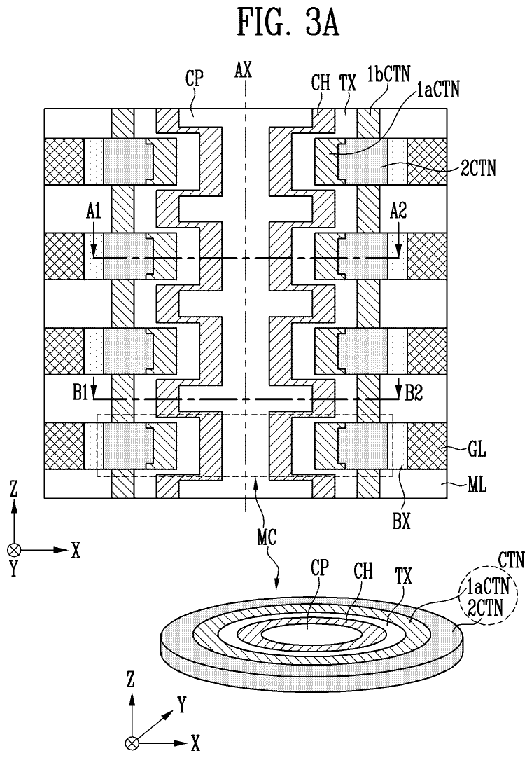

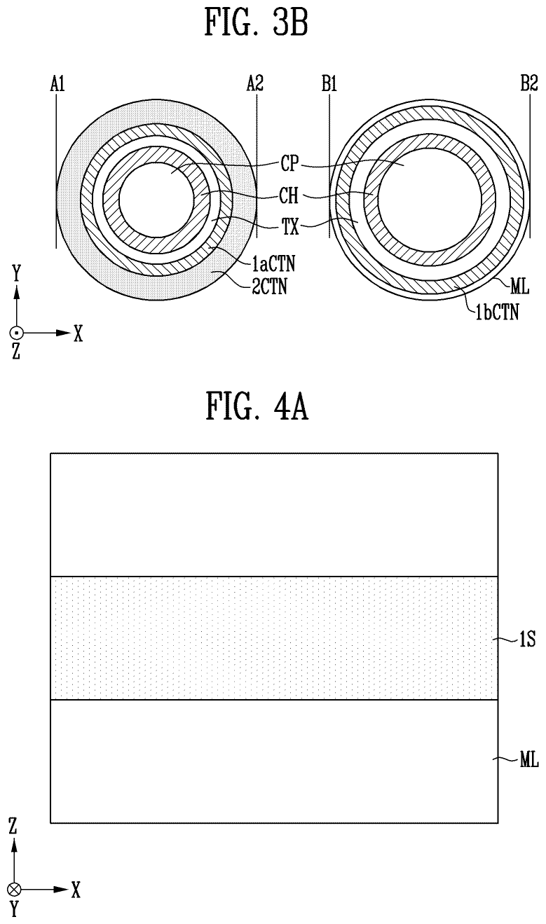

FIGS. 3A and 3B are views illustrating the structure of a memory device according to first embodiments of the present disclosure.

Referring to FIGS. 3A and 3B, memory cells MC may be stacked in a Z direction. When any one memory cell MC is described by way of example, the memory cell MC may be surrounded by a gate line GL. A blocking layer BX may be disposed between the gate line GL and the memory cell MC. The gate line GL may be formed of a conductive material. For example, the gate line GL may be formed of a metal material such as tungsten (W), molybdenum (Mo), cobalt (Co), or nickel (Ni), or a semiconductor material such as silicon (Si) or polysilicon (Poly-Si). The blocking layer BX may be formed of an insulating material. For example, the blocking layer BX may be formed of a silicon oxide material.

The memory cell MC may have a circular or elliptical shape in the XY plane, but the shape of the memory cell MC is not limited to the circular or elliptical shape. Referring to the A1-A2 plane, the memory cell MC may include a 1a-th charge trap layer 1aCTN (i.e., first charge trap layer), a second charge trap layer 2CTN, a tunnel isolation layer TX, a channel layer CH, and a core pillar CP. The core pillar CP may be disposed at the center of the memory cell MC with respect to the central axis AX in the Z direction. The channel layer CH may surround the core pillar CP.

Each of the 1a-th charge trap layer 1aCTN and the second charge trap layer 2CTN may be formed of a nitride material. The second charge trap layer 2CTN may be formed of a material having charge trapping ability lower than that of the 1a-th charge trap layer 1aCTN. When the 1a-th charge trap layer 1aCTN and the second charge trap layer 2CTN are formed of silicon nitride (SiN) or silicon oxynitride (SiON), the concentration of nitrogen contained in the second charge trap layer 2CTN may be higher than that of nitrogen contained in the 1a-th charge trap layer 1aCTN. Alternatively, the 1a-th charge trap layer 1aCTN may be formed of silicon nitride (SIN), and the second charge trap layer 2CTN may be formed of silicon oxynitride (SiON). The tunnel isolation layer TX may be formed of an insulating material. For example, the tunnel isolation layer TX may be formed of a silicon oxide material. The channel layer CH may be formed of polysilicon. The core pillar CP may be formed of an insulating material or a conductive material.

Referring to the B1-B2 plane, a material layer ML, a 1b-th charge trap layer 1bCTN (i.e., third or fourth charge trap layer), the tunnel isolation layer TX, the channel layer CH, and the core pillar CP may be disposed between the memory cells MC. The core pillar CP may extend in the Z direction along the central axis AX in the Z direction even between the memory cells MC. The tunnel isolation layer TX may surround the outside of the core pillar CP. The 1b-th charge trap layer 1bCTN may surround the outside of the tunnel isolation layer TX. The material layer ML may surround the outside of the 1b-th charge trap layer 1bCTN. The 1b-th charge trap layer 1bCTN may be formed of the same material as the 1a-th charge trap layer 1aCTN.

The core pillar CP extending along the axis AX in the Z direction may have an uneven structure. For example, the core pillar CP may have protrusions protruding from the axis AX between the memory cells MC. Therefore, the channel layer CH surrounding the core pillar CP may also have an uneven structure along the outer surface of the core pillar CP. For example, the channel layer CH included in each memory cell MC may have a structure depressed toward the central axis AX, and the channel layer CH between the memory cells MC may have a structure protruding from the central axis AX. Therefore, the channel layer CH having the uneven structure may extend in the Z direction. The tunnel isolation layer TX surrounding the channel layer CH may also have an uneven structure along the outer surface of the channel layer CH. For example, the tunnel isolation layer TX included in each memory cell MC may have a structure depressed toward the central axis AX, and the tunnel isolation layer TX between the memory cells MC may have a structure protruding from the central axis AX. The tunnel isolation layer TX having the uneven structure may extend along the Z direction.

The 1a-th charge trap layer 1aCTN may surround the tunnel isolation layer TX of each memory cell MC, and the 1b-th charge trap layer 1bCTN may surround the tunnel isolation layer TX between the memory cells MC. The 1a-th charge trap layer 1aCTN and the 1b-th charge trap layer 1bCTN may be separated from each other.

The second charge trap layers 2CTN of respective memory cells MC may be separated from each other between the memory cells MC, and may each be surrounded by the tunnel isolation layer TX, the 1a-th charge trap layer 1aCTN, the 1b-th charge trap layer 1bCTN, and the blocking layer BX. For example, a portion of an area of the second charge trap layer 2CTN, contacting the 1a-th charge trap layer 1aCTN, may protrude toward the central axis AX. Portions of the top surface and the bottom surface of the second charge trap layer 2CTN may contact the tunnel isolation layer TX, and the remaining portions of the top surface and the bottom surface thereof may contact the 1b-th charge trap layer 1bCTN (i.e., third charge trap layer contacting a top of the second charge trap layer 2CTN and fourth charge trap layer contacting a bottom of the second charge trap layer 2CTN). The outer side surface of the second charge trap layer 2CTN may contact the blocking layer BX. The gate line GL may be surrounded by the blocking layer BX and the material layers ML.

In an embodiment of the structure of the above-described memory device, second charge trap layers 2CTN included in respective memory cells MC are separated from each other between the memory cells MC, and thus the retention characteristics of electrons trapped in the second charge trap layers 2CTN during a program operation may be improved. Although, in an embodiment, the 1b-th charge trap layer 1bCTN is disposed between the second charge trap layers 2CTN adjacent to each other in the Z direction is disposed, the second charge trap layers 2CTN are formed of a material having charge trapping ability lower than that of the 1b-th charge trap layer 1bCTN, thus improving the retention characteristics of the memory cells MC.

A method of manufacturing the above-described memory device according to the first embodiments will be described below.

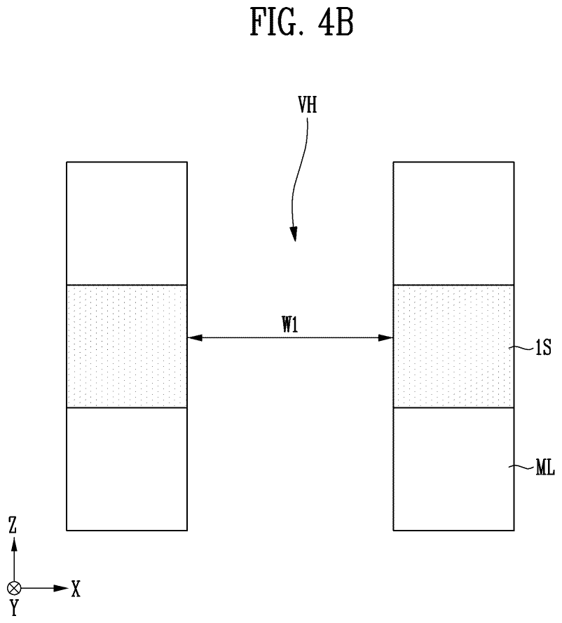

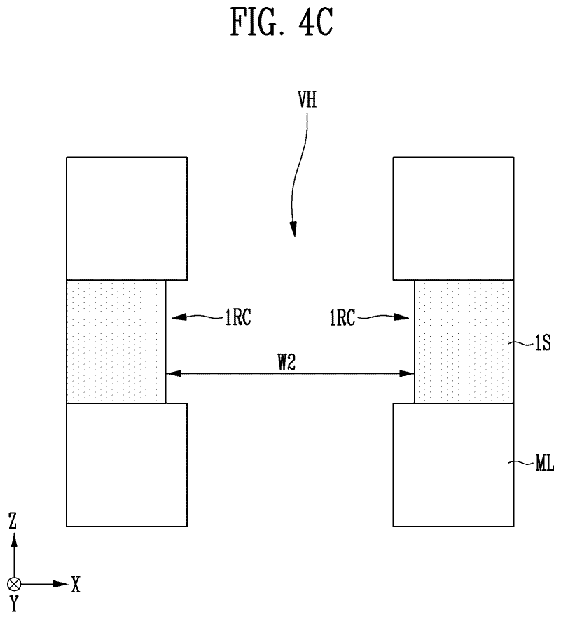

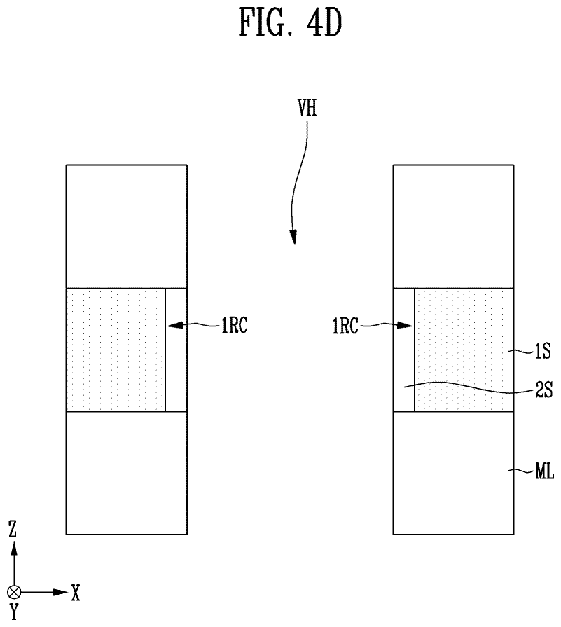

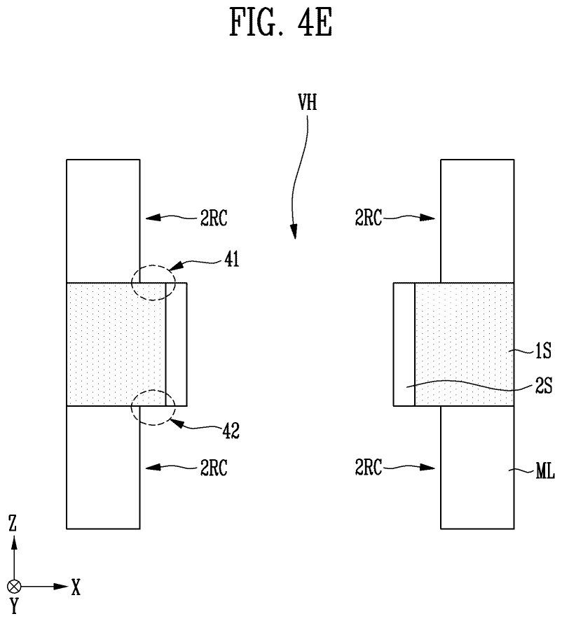

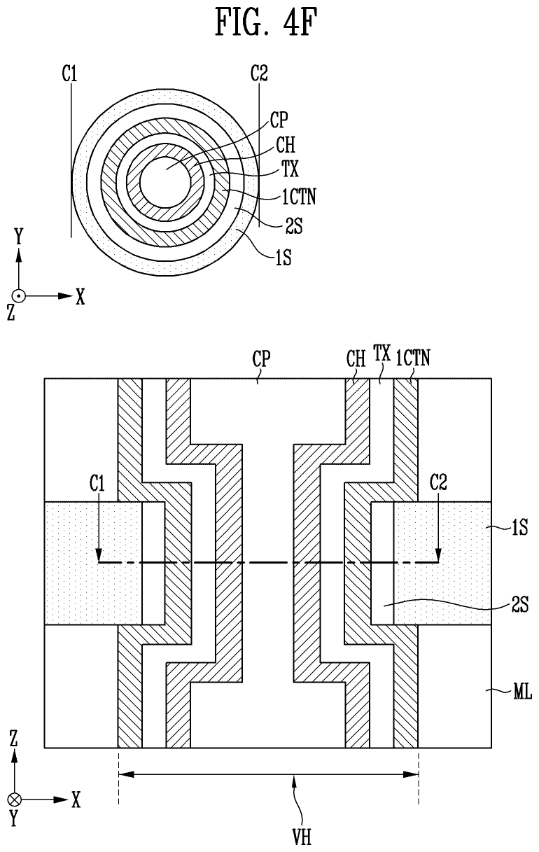

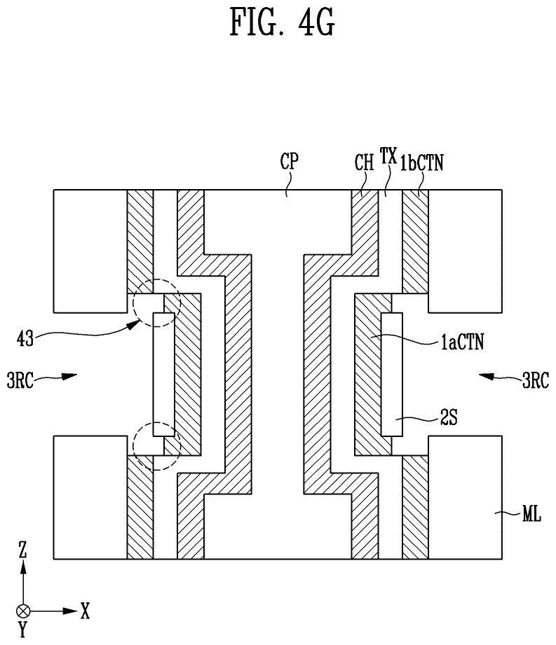

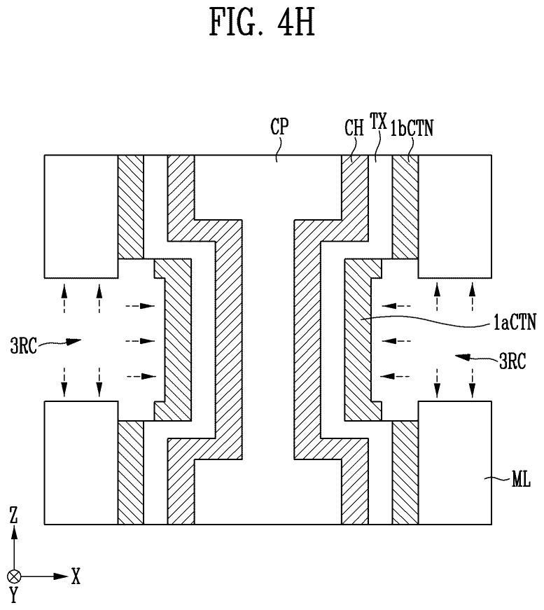

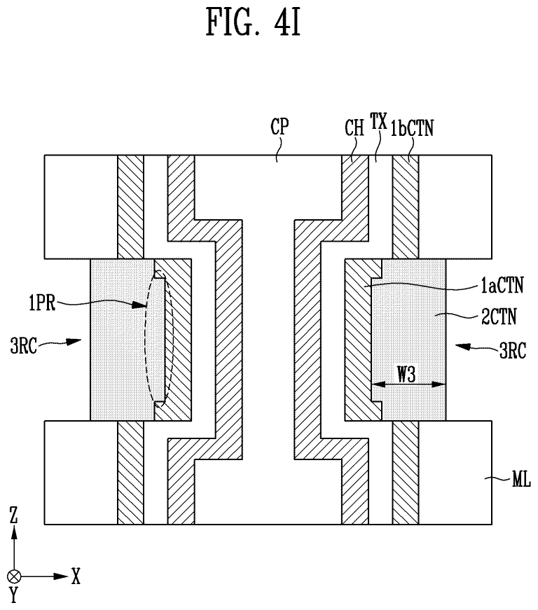

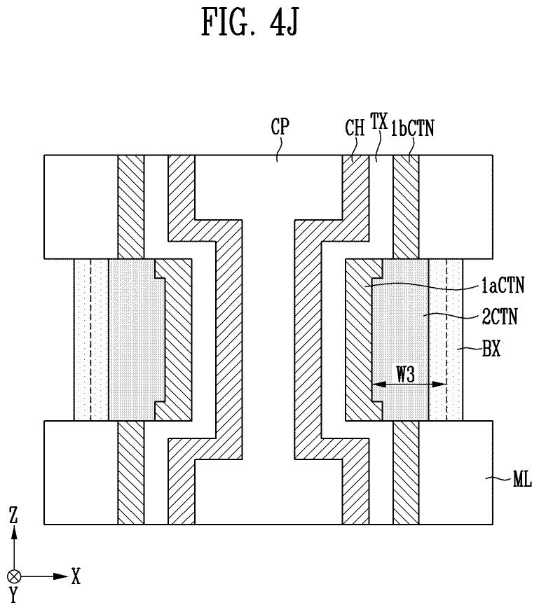

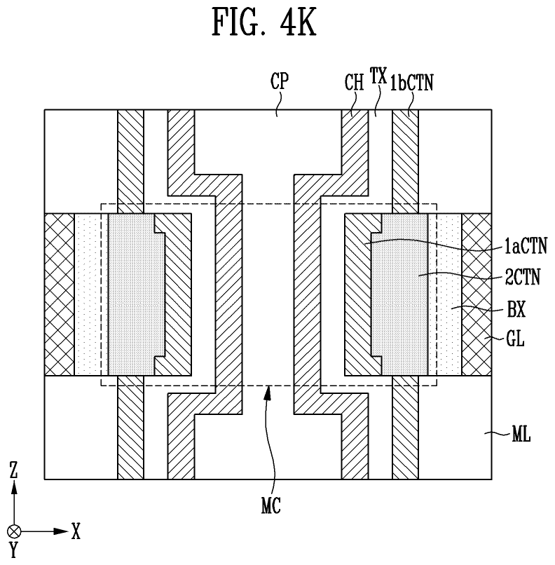

FIGS. 4A to 4K are views illustrating a method of manufacturing the memory device according to the first embodiments of the present disclosure.

Referring to FIG. 4A, material layers ML and first sacrificial layers 1S may be stacked along a Z direction. For example, the material layers ML and the first sacrificial layers 1S may be stacked on a lower structure (not illustrated) including a substrate or a peripheral circuit. Each of the material layers ML may be formed of an insulating material. For example, each of the material layers ML may be formed of a silicon oxide material. Each of the first sacrificial layers 1S may be formed of a nitride material. For example, each of the first sacrificial layers 1S may be formed of a silicon nitride material.

Referring to FIG. 4B, a vertical hole VH vertically passing through (i.e., Z direction) the material layers ML and the first sacrificial layers 1S may be formed. For example, the vertical hole VH may be formed by performing a dry etching process. For example, as the dry etching process for forming the vertical hole VH, an anisotropic dry etching process may be performed. A width between the first sacrificial layers 1S exposed through the vertical VH and facing each other may be a first width W1.

Referring to FIG. 4C, an etching process for selectively removing portions of the first sacrificial layers 1S exposed through the vertical hole VH may be performed. For example, a selective etching process using an etchant with which the selectivity of the first sacrificial layers 1S is higher than that of the material layers ML may be performed. Assuming that regions from which portions of the first sacrificial layers 1S are removed by the selective etching process are first recesses 1RC, the width between the first sacrificial layers 1S may increase from the first width W1 to a second width W2 due to the first recesses 1RC. As an etching process for selectively removing the portions of the first sacrificial layers 1S, an isotropic etching process may be performed.

Referring to FIG. 4D, second sacrificial layers 2S may be formed in the first recesses 1RC. The second sacrificial layers 2S may be selectively formed along the first sacrificial layers 1S exposed through the first recesses 1RC. For example, the second sacrificial layers 2S might not be formed on the material layers ML, but may be grown from the first sacrificial layers 1S exposed between the material layers ML, by means of an area selective deposition (ASD) method. Each of the second sacrificial layers 2S may be formed of a low-dielectric constant (low-k) material. For example, each of the second sacrificial layers 2S may be formed of silicon oxycarbide (SiOC).

Referring to FIG. 4E, an etching process for selectively removing portions of the material layers ML exposed through the vertical hole VH may be performed. For example, a selective etching process using an etchant with which the selectivity of the material layers ML is higher than that of the first and second sacrificial layers 1S and 2S may be performed. That is, when the etching process for the material layers ML is performed, the second sacrificial layers 2S may be used as etch stop layers.

Assuming that regions from which portions of the material layers ML are removed by the selective etching process are second recesses 2RC, a partial top surface 41 and a partial bottom surface 42 of each of the first sacrificial layers 1S may be exposed through the second recesses 2RC. As the etching process for selectively removing the portions of the material layers ML, an isotropic etching process may be performed.

Referring to FIG. 4F, a first charge trap layer 1CTN, a tunnel isolation layer TX, a channel layer CH, and a core pillar CP may be sequentially formed in the vertical hole VH. The first charge trap layer 1CTN may be formed of a nitride material. For example, the first charge trap layer 1CTN may be formed of SIN or SiON. Because the side surface of the vertical hole VH has an uneven structure, as illustrated in FIG. 4E, the first charge trap layer 1CTN may be formed along the uneven structure. The tunnel isolation layer TX formed along the side surface of the first charge trap layer 1CTN may be formed of an insulating material. For example, the tunnel isolation layer TX may be formed of a silicon oxide material. The channel layer CH formed along the side surface of the tunnel isolation layer TX may be formed of polysilicon. The core pillar CP filling a region surrounded by the channel layer CH may be formed of an insulating material or a conductive material. Referring to the C1-C2 plane in a region surrounded by the first sacrificial layer 1S, the core pillar CP may be disposed at the center, and the channel layer CH may surround the core pillar CP. The tunnel isolation layer TX may surround the channel layer CH, and the first charge trap layer 1CTN may surround the tunnel isolation layer TX. The second sacrificial layer 2S may surround the first charge trap layer 1CTN, and the first sacrificial layer 1S may surround the second sacrificial layer 2S.

Referring to FIG. 4G, an etching process for forming third recesses 3RC by removing the first sacrificial layers (e.g., 1S of FIG. 4F) may be performed. For example, a selective etching process using an etchant with which the selectivity of the first sacrificial layers (e.g., 1S of FIG. 4F) is higher than that of the material layers ML and the second sacrificial layers 2S may be performed. Therefore, when the first sacrificial layers (e.g., 1S of FIG. 4F) are removed, portions of the second sacrificial layers 2S and the first charge trap layer (e.g., 1CTN of FIG. 4F) may be exposed through the third recesses 3RC. During the etching process for removing the first sacrificial layers (e.g., 1S of FIG. 4F), a portion of the first charge trap layer (e.g., 1CTN of FIG. 4F) exposed between the second sacrificial layers 2S and the material layers ML may be removed. When the portion of the first charge trap layer (e.g., 1CTN of FIG. 4F) is removed, the first charge trap layer (e.g., 1CTN of FIG. 4F) may be separated into a 1a-th charge trap layer 1aCTN and a 1b-th charge trap layer 1bCTN. During the etching process for removing the first sacrificial layers (e.g., 1S of FIG. 4F), when the first charge trap layer (e.g., 1CTN of FIG. 4F) is not separated into the 1a-th charge trap layer 1aCTN and the 1b-th charge trap layer 1bCTN, an etching process for separating the first charge trap layer (e.g., 1CTN of FIG. 4F) into the 1a-th charge trap layer 1aCTN and the 1b-th charge trap layer 1bCTN may be additionally performed. The etching process to be additionally performed may be performed using an etchant with which the selectivity of the first charge trap layer (e.g., 1CTN of FIG. 4F) is higher than that of the material layers ML and the second sacrificial layers 2S.

Referring to FIG. 4H, an etching process for removing the second sacrificial layers (e.g., 2S of FIG. 4G) and portions of the material layers ML, which are exposed through the third recesses 3RC, may be performed. The etching process may be performed until the second sacrificial layers (e.g., 2S of FIG. 4G) are completely removed. When the second sacrificial layers (e.g., 2S of FIG. 4G) are removed, the 1a-th charge trap layer 1aCTN may be exposed. That is, through the third recesses 3RC, the material layers ML, 1a-th charge trap layers 1aCTN, and 1b-th charge trap layers 1bCTN may be exposed. A portion of the tunnel isolation layer TX may be exposed between the 1a-th charge trap layers 1aCTN and the 1b-th charge trap layers 1bCTN. When the second sacrificial layers (e.g., 2S of FIG. 4G) are removed, each of the 1a-th charge trap layers 1aCTN exposed through the third recesses 3RC has an uneven structure.

Referring to FIG. 4I, second charge trap layers 2CTN contacting the 1a-th charge trap layers 1aCTN and the 1b-th charge trap layers 1bCTN, which are exposed through the third recesses 3RC, may be formed. Each of the second charge trap layers 2CTN may be formed of a nitride material. The second charge trap layers 2CTN may be formed of a material having charge trapping ability lower than that of the 1a-th and 1b-th charge trap layers 1aCTN and 1bCTN. For example, the concentration of nitrogen contained in the second charge trap layers 2CTN may be higher than that of nitrogen contained in the 1a-th and 1b-th charge trap layers 1aCTN and 1bCTN. Alternatively, when the 1a-th and 1b-th charge trap layers 1aCTN and 1bCTN are formed of SIN, the second charge trap layers 2CTN may be formed of SiON.

The second charge trap layers 2CTN may be formed in such a way as to be selectively grown from the 1a-th and 1b-th charge trap layers 1aCTN and 1bCTN. Therefore, the second charge trap layers 2CTN may contact the 1a-th and 1b-th charge trap layers 1aCTN and 1bCTN in the third recesses 3RC, and portions of the material layers ML may be exposed through the third recesses 3RC. The second charge trap layers 2CTN may be grown until they cover the 1a-th and 1b-th charge trap layers 1aCTN and 1bCTN in the third recesses 3RC. For example, the largest width of the second charge trap layers 2CTN may be a third width W3. Because portions of the 1a-th charge trap layers 1aCTN contacting the second charge trap layers 2CTN are depressed toward the tunnel isolation layers TX, the second charge trap layers 2CTN may include first protrusions 1PR protruding toward the 1a-th charge trap layers 1aCTN. The areas of the second charge trap layers 2CTN may be increased due to the first protrusions 1PR.

Referring to FIG. 4J, blocking layers BX may be formed on the second charge trap layers 2CTN. Each of the blocking layers BX may be formed of an insulating material. For example, each of the blocking layers BX may be formed of a silicon oxide material. The blocking layers BX may be formed in such a way as to be selectively grown from the second charge trap layers 2CTN. The blocking layers BX may be formed on portions of the second charge trap layers 2CTN exposed through the third recesses 3RC and the surfaces of the second charge trap layers 2CTN. Therefore, the largest width of the second charge trap layers 2CTN may become smaller than the third width W3.

Referring to FIG. 4K, gate lines GL may be formed in regions surrounded by the blocking layers BX and the material layers ML. Because the gate lines GL are used as word lines or select lines, the gate lines GL may be formed of a conductive material. For example, the gate lines GL may be formed of a metal material such as tungsten (W), molybdenum (Mo), cobalt (Co), or nickel (Ni), or a semiconductor material such as silicon (Si) or polysilicon (Poly-Si).

By the above-described manufacturing method, memory cells MC to be electrically connected to the gate lines GL may be formed. When one memory cell MC is described by way of example, the memory cell MC may include a second charge trap layer 2CTN and a 1a-th charge trap layer 1aCTN which trap charges. Although, in an embodiment, 1b-th charge trap layers 1bCTN are disposed between the second charge trap layers 2CTN of the memory cells MC adjacent to each other in the Z direction, the second charge trap layers 2CTN are formed to be capable of trapping more charges than the 1a-th and 1b-th charge trap layers 1aCTN and 1bCTN. Therefore, in an embodiment, more charges may be trapped in the second charge trap layers 2CTN than in the 1a-th and 1b-th charge trap layers 1aCTN and 1bCTN during a program operation of the memory device. Therefore, in an embodiment, interference that may occur between the memory cells MC adjacent to each other in the Z direction may be reduced, and the retention characteristics of the memory cells MC may be improved.

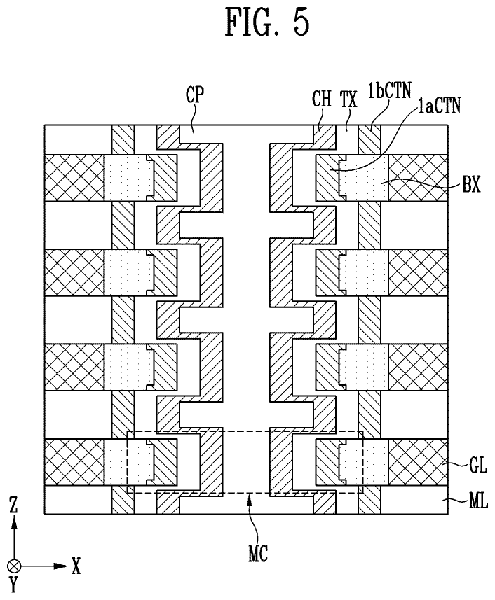

FIG. 5 is a view illustrating the structure of a memory device according to second embodiments of the present disclosure.

Referring to FIG. 5, the memory device according to the second embodiments might not include second charge trap layers (e.g., 2CTN of FIG. 3A). For example, because the memory device according to the second embodiments do not include second charge trap layers, 1a-th charge trap layers 1aCTN (i.e., first charge trap layer) and blocking layers BX may contact each other. Further, the blocking layers BX may also contact 1b-th charge trap layers 1bCTN (i.e., second charge trap layer 1bCTN contacting a top of the blocking layer BX and third charge trap layer 1bCTN contacting a bottom of the blocking layer BX). Because the 1a-th charge trap layers 1aCTN and the 1b-th charge trap layers 1bCTN are separated from each other in an embodiment, charges may be trapped in the 1a-th charge trap layers 1aCTN, and might not be trapped in the 1b-th charge trap layers 1bCTN.

Because, in an embodiment, the 1a-th charge trap layers 1aCTN are included only in the memory cells MC and are not disposed between the memory cells MC, interference between the memory cells MC adjacent to each other in the Z direction may be reduced.

Each of the 1a-th charge trap layers 1aCTN may be formed of a nitride material. In the memory device according to the first embodiments, the 1b-th charge trap layers 1bCTN contact the tops and bottoms of the second charge trap layers 2CTN, and thus the second charge trap layers 2CTN are formed of a material having charge trapping ability lower than that of the 1a-th charge trap layers 1aCTN. In the memory device according to the second embodiments, charges are trapped only in the 1a-th charge trap layers 1aCTN, and thus the 1a-th charge trap layers 1aCTN may be formed of SiN or SiON regardless of nitrogen concentration.

A method of manufacturing the above-described memory device according to the second embodiments will be described below.

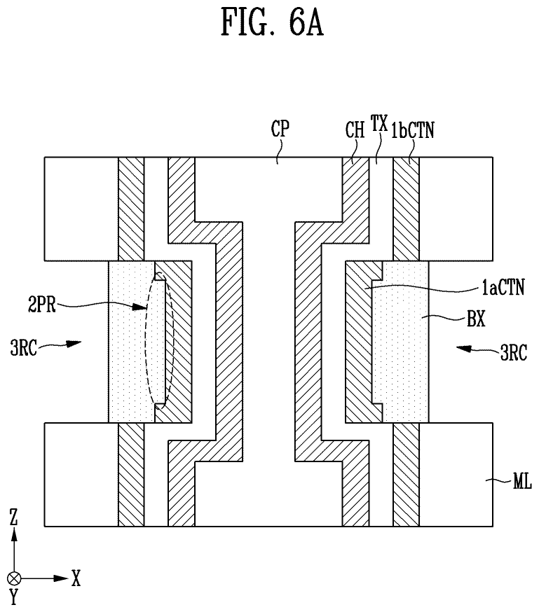

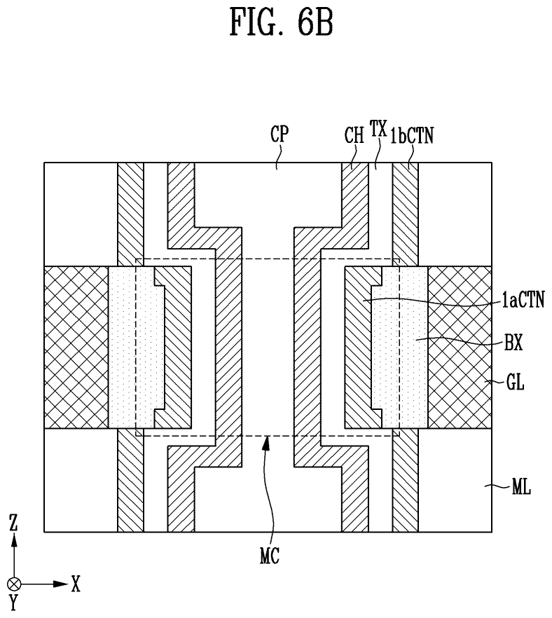

FIGS. 6A and 6B are views illustrating a method of manufacturing the memory devices according to the second embodiments of the present disclosure.

In the method of manufacturing the memory devices according to the first embodiments, the manufacturing method described above with reference to FIGS. 4A to 4H overlaps the method of manufacturing the memory devices according to the second embodiments, and thus repeated descriptions of overlapping configurations is omitted.

Referring to FIG. 6A, after the manufacturing method described with reference to FIGS. 4A to 4H, blocking layers BX may be formed on 1a-th charge trap layers 1aCTN exposed through third recesses 3RC. Each of the blocking layers BX may be formed of a silicon oxide material that is an insulating material. For example, each of the blocking layers BX may be formed of silicon oxycarbide (SiOC). The blocking layers BX may be formed in such a way as to be selectively grown from the 1a-th charge trap layers 1aCTN. The blocking layers BX may be formed on portions of the 1a-th charge trap layers 1aCTN exposed to the third recesses 3RC and 1b-th charge trap layers 1bCTN exposed through the third recesses 3RC. After the blocking layers BX are formed, a heat treatment process may be additionally performed. Because portions of the 1a-th charge trap layers 1aCTN contacting the blocking layers BX are depressed toward tunnel isolation layers TX, the blocking layers BX may include second protrusions 2PR protruding toward the 1a-th charge trap layers 1aCTN.

Referring to FIG. 6B, gate lines GL may be formed in regions surrounded by the blocking layers BX and material layers ML. Because the gate lines GL are used as word lines or select lines, the gate lines GL may be formed of a conductive material. For example, the gate lines GL may be formed of a metal material such as tungsten (W), molybdenum (Mo), cobalt (Co), or nickel (Ni), or a semiconductor material such as silicon (Si) or polysilicon (Poly-Si).

As described above, in an embodiment, the 1a-th charge trap layers 1aCTN included in the memory cells MC are spaced apart from each other along the Z direction, thus reducing interference that may occur between the memory cells MC adjacent to each other in the Z direction and improving the retention characteristics of the memory cells MC.

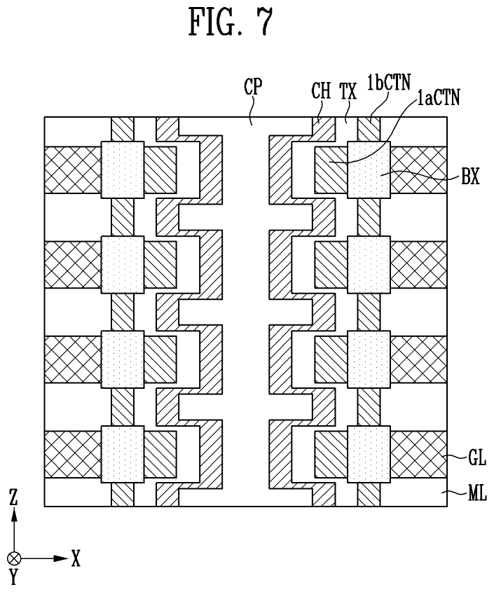

FIG. 7 is a view illustrating the structure of memory devices according to third embodiments of the present disclosure.

Referring to FIG. 7, the memory devices according to the third embodiments might not include second charge trap layers (e.g., 2CTN of FIG. 3A), as in the case of the memory devices according to the second embodiments. In the third embodiments, at a manufacturing step, second sacrificial layers (e.g., 2S of FIG. 4G) are not formed. Therefore, the uneven structure of the 1a-th charge trap layers 1aCTN in the first and second embodiments are not formed in the 1a-th charge trap layers 1aCTN in the third embodiments.

Because, in the memory devices according to the third embodiments, the 1a-th charge trap layers 1aCTN and the 1b-th charge trap layers 1bCTN are separated from each other by the blocking layers BX, charges may be trapped in the 1a-th charge trap layers 1aCTN, and might not be trapped in the 1b-th charge trap layers 1bCTN.

Because, in an embodiment, the 1a-th charge trap layers 1aCTN are included only in the memory cells MC and are not disposed between the memory cells MC, interference between the memory cells MC adjacent to each other in the Z direction may be reduced.

Each of the 1a-th charge trap layers 1aCTN may be formed of a nitride material. In the memory device according to the first embodiment, the 1b-th charge trap layers 1bCTN contact the tops and bottoms of the second charge trap layers 2CTN, and thus the second charge trap layers 2CTN are formed of a material having charge trapping ability lower than that of the 1a-th charge trap layers 1aCTN. In the memory device according to the second embodiments, charges are trapped only in the 1a-th charge trap layers 1aCTN, and thus the 1a-th charge trap layers 1aCTN may be formed of SIN or SiON regardless of nitrogen concentration. A method of manufacturing the above-described memory devices according to the third embodiments will be described below.

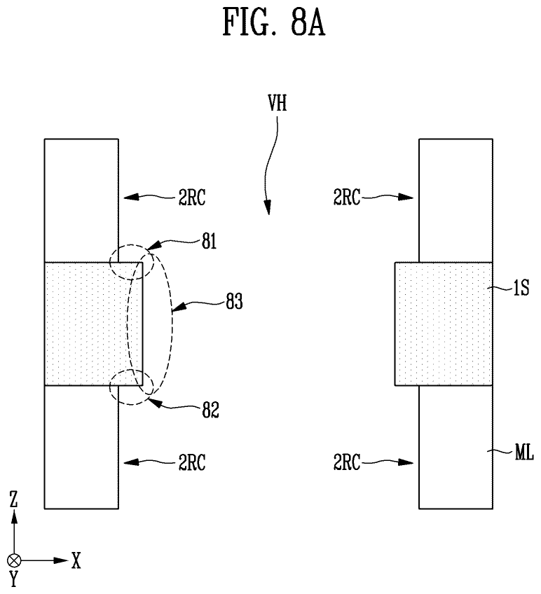

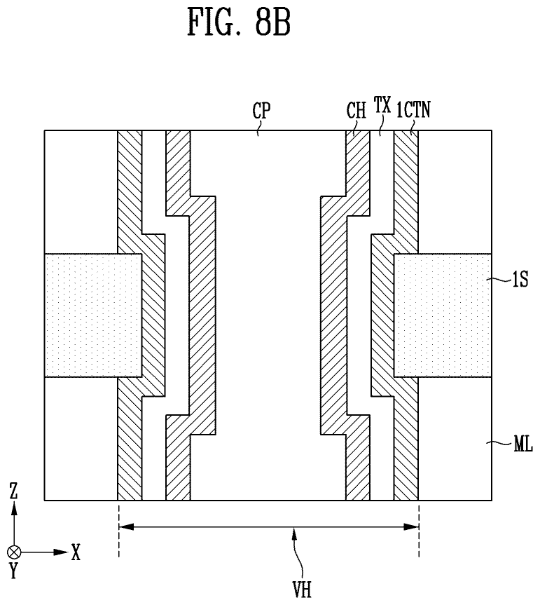

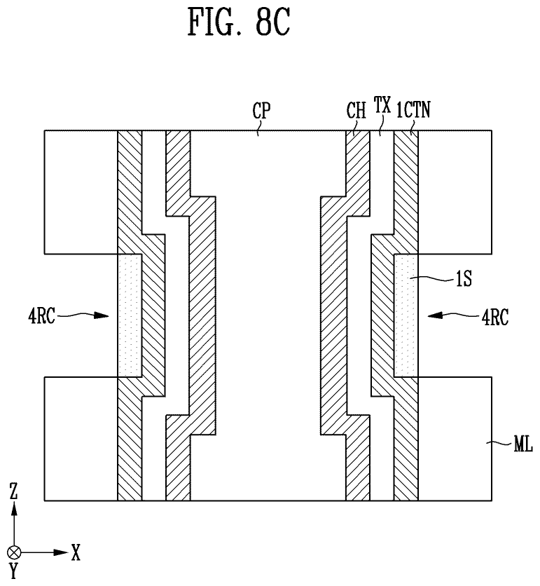

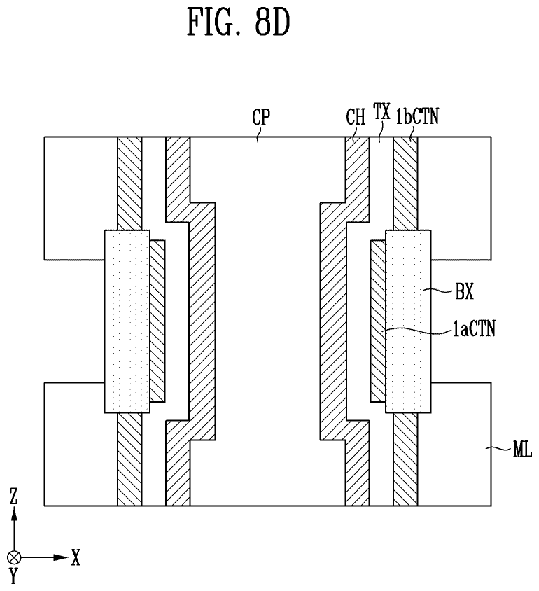

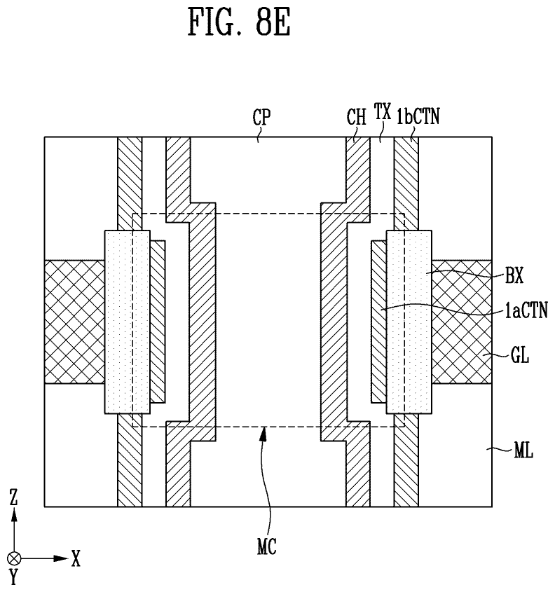

FIGS. 8A to 8E are views illustrating a method of manufacturing the memory devices according to the third embodiments of the present disclosure.

In the method of manufacturing the memory devices according to the first embodiments, the manufacturing method described above with reference to FIGS. 4A and 4B overlaps the method of manufacturing the memory devices according to the third embodiments, and thus repeated description of overlapping configurations is omitted.

Referring to FIG. 8A, after the manufacturing method described above with reference to FIG. 4B, an etching process for selectively removing portions of material layers ML exposed through a vertical hole VH may be performed. For example, a selective etching process using an etchant with which the selectivity of material layers ML is higher than that of first sacrificial layers 1S may be performed. Assuming that regions from which portions of the material layers ML are removed by the selective etching process are second recesses 2RC, a partial top surface 81, a partial bottom surface 82, and a side surface 83 of each of the first sacrificial layers 1S may be exposed through the second recesses 2RC. As the etching process for selectively removing the portions of the material layers ML, an isotropic etching process may be performed.

Referring to FIG. 8B, a first charge trap layer 1CTN, a tunnel isolation layer TX, a channel layer CH, and a core pillar CP may be sequentially formed in the vertical hole VH. The first charge trap layer 1CTN may be formed of a nitride material. For example, the first charge trap layer 1CTN may be formed of SIN or SiON. Because the side surface of the vertical hole VH has an uneven structure, the first charge trap layer 1CTN may be formed along the uneven structure. The tunnel isolation layer TX formed along the side surface of the first charge trap layer 1CTN may be formed of an insulating material. For example, the tunnel isolation layer TX may be formed of a silicon oxide material. The channel layer CH formed along the side surface of the tunnel isolation layer TX may be formed of polysilicon. The core pillar CP filling a region surrounded by the channel layer CH may be formed of an insulating material or a conductive material.

Referring to FIG. 8C, an etching process for forming fourth recesses 4RC by removing portions of the first sacrificial layers 1S may be performed. For example, a selective etching process using an etchant with which the selectivity of the first sacrificial layers 1S is higher than that of the material layers ML may be performed. Therefore, when the portions of the first sacrificial layers 1S are removed, portions of the first sacrificial layers 1S and the material layers ML may be exposed through the fourth recesses 4RC. During the etching process for removing the portions of the first sacrificial layers 1S, a portion of the first charge trap layer 1CTN may be exposed.

Referring to FIG. 8D, an oxidization process for converting the first sacrificial layers 1S into blocking layers BX may be performed. For example, the first sacrificial layers 1S may be converted into blocking layers BX formed of a silicon oxide material or SiOC through the oxidization process. When the oxidization process is performed even after the first sacrificial layers 1S are converted into the blocking layers BX, layers contacting the blocking layers BS may also be oxidized. Due thereto, the first charge trap layers (e.g., 1CTN of FIG. 8C) may be separated into 1a-th charge trap layers 1aCTN and 1b-th charge trap layers 1bCTN.

Referring to FIG. 8E, gate lines GL may be formed in regions surrounded by the blocking layers BX and the material layers ML. Because the gate lines GL are used as word lines or select lines, the gate lines GL may be formed of a conductive material. For example, the gate lines GL may be formed of a metal material such as tungsten (W), molybdenum (Mo), cobalt (Co), or nickel (Ni), or a semiconductor material such as silicon (Si) or polysilicon (Poly-Si).

As described above, in an embodiment, the 1a-th charge trap layers 1aCTN included in the memory cells MC are spaced apart from each other along the Z direction, thus reducing interference that may occur between the memory cells MC adjacent to each other in the Z direction and improving the retention characteristics of the memory cells MC.

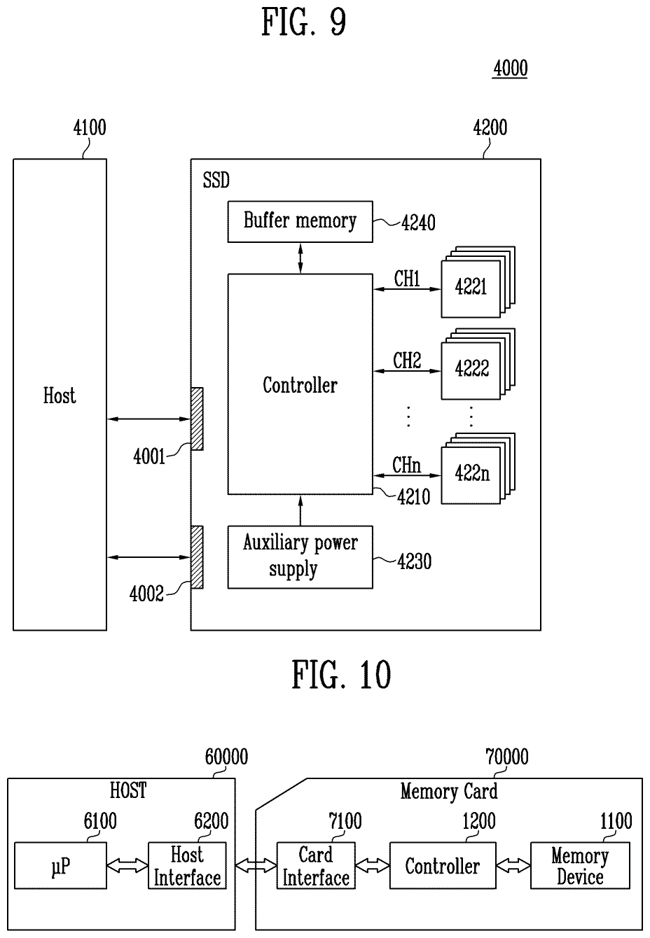

FIG. 9 is a diagram illustrating a solid state drive (SSD) system to which a memory device according to the present disclosure is applied.

Referring to FIG. 9, an SSD system 4000 includes a host 4100 and an SSD 4200. The SSD 4200 may exchange a signal with the host 4100 through a signal connector 4001, and may receive power through a power connector 4002. The SSD 4200 may include a controller 4210, memory devices 4221 to 422n, an auxiliary power supply 4230, and a buffer memory 4240.

According to an embodiment of the present disclosure, each of the memory devices 4221 to 422n may be configured in the same manner as the memory device 100 described above with reference to FIG. 1.

The controller 4210 may control the memory devices 4221 to 422n in response to a signal received from the host 4100. In an embodiment, the signal may include signals based on the interfaces of the host 4100 and the SSD 4200. For example, the signal may be a signal defined by at least one of interfaces such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe).

The auxiliary power supply 4230 may be coupled to the host 4100 through the power connector 4002. The auxiliary power supply 4230 may be supplied with a supply voltage from the host 4100, and may be charged with the supply voltage. The auxiliary power supply 4230 may provide the supply voltage to the SSD 4200 when the supply of power from the host 4100 is not smoothly performed. In an embodiment, the auxiliary power supply 4230 may be located inside the SSD 4200 or located outside the SSD 4200. For example, the auxiliary power supply 4230 may be located on a main board, and may also provide auxiliary power to the SSD 4200.

The buffer memory 4240 may be used as a buffer memory of the SSD 4200. For example, the buffer memory 4240 may store data received from the host 4100 or data received from the memory devices 4221 to 422n, or may store metadata (e.g., mapping tables) of the memory devices 4221 to 422n. The buffer memory 4240 may include volatile memories, such as DRAM, SDRAM, DDR SDRAM, and LPDDR SDRAM, or nonvolatile memories, such as FRAM, ReRAM, STT-MRAM, and PRAM.

FIG. 10 is a diagram illustrating a memory card system to which a memory device according to the present disclosure is applied.

Referring to FIG. 10, a memory system 70000 may be implemented as a memory card or a smart card. The memory system 70000 may include a memory device 1100, a controller 1200, and a card interface 7100.

The memory device 1100 may be configured in the same manner as the memory device 100 illustrated in FIG. 1.

The controller 1200 may control data exchange between the memory device 1100 and the card interface 7100. In an embodiment, the card interface 7100 may be, but is not limited to, a secure digital (SD) card interface or a multimedia card (MMC) interface.

The card interface 7100 may interface data exchange between a host 60000 and the controller 1200 according to a protocol of the host 60000. In accordance with an embodiment, the card interface 7100 may support a universal serial bus (USB) protocol and an interchip (IC)-USB protocol. Here, the card interface 7100 may refer to hardware capable of supporting the protocol which is used by the host 60000, software installed in the hardware, or a signal transmission method.

When the memory system 70000 is coupled to a host interface 6200 of the host 60000 such as a PC, a tablet PC, a digital camera, a digital audio player, a mobile phone, console video game hardware or a digital set-top box, the host interface 6200 may perform data communication with the memory device 1100 through the card interface 7100 and the controller 1200 under the control of a microprocessor (UP) 6100.

An embodiment of the present disclosure may improve the retention characteristics of a memory device.

What is claimed is:

1. A memory device, comprising:
a channel layer extending in a first direction;
a tunnel isolation layer extending in the first direction and surrounding the channel layer;
a first charge trap layer surrounding a portion of the tunnel isolation layer;
a second charge trap layer surrounding the first charge trap layer; and
a blocking layer surrounding the second charge trap layer,
wherein the second charge trap layer is configured to trap more charges than the first charge trap layer.

2. The memory device according to claim 1, wherein each of the first and second charge trap layers is formed of a nitride material.

3. The memory device according to claim 1, wherein each of the first and second charge trap layers is formed of silicon nitride (SiN) or silicon oxynitride (SiON).

4. The memory device according to claim 1, wherein the first charge trap layer is formed of SiN and the second charge trap layer is formed of SiON.

5. The memory device according to claim 1, wherein the second charge trap layer has a nitrogen concentration higher than the first charge trap layer.

6. The memory device according to claim 1, wherein the tunnel isolation layer is configured to:
extend from a first side of the first charge trap layer in the first direction, and
extend in a second directional substantially orthogonal to the first direction on a top surface and a bottom surface of the first charge trap layer.

7. The memory device according to claim 1, wherein, in a portion in which the first and second charge trap layers contact each other, the second charge trap layer includes a protrusion protruding toward the first charge trap layer.

8. The memory device according to claim 1, further comprising:
a third charge trap layer contacting a top of the second charge trap layer; and
a fourth charge trap layer contacting a bottom of the second charge trap layer.

9. The memory device according to claim 8, wherein each of the third and fourth charge trap layers is formed of a material substantially identical to that of the first charge trap layer.

10. The memory device according to claim 8, wherein the third and fourth charge trap layers are spaced apart from the first charge trap layer.

11. A memory device, comprising:
a channel layer including an uneven structure and extending in a vertical direction;
a tunnel isolation layer including the uneven structure and surrounding the channel layer;
a first charge trap layer disposed in a depressed portion of the tunnel isolation layer;
a blocking layer surrounding the first charge trap layer;
a second charge trap layer contacting a top of the blocking layer; and
a third charge trap layer contacting a bottom of the blocking layer.

12. The memory device according to claim 11, wherein each of the first to third charge trap layers is formed of a nitride material.

13. The memory device according to claim 11, wherein each of the first to third charge trap layers is formed of silicon nitride (SiN) or silicon oxynitride (SiON).

14. The memory device according to claim 11, wherein the second and third charge trap layers are spaced apart from the first charge trap layer.

15. The memory device according to claim 11, wherein, in a portion in which the blocking layer and the first charge trap layer contact each other, the blocking layer includes a protrusion protruding toward the first charge trap layer.

16. The memory device according to claim 11, wherein a length of the blocking layer in the vertical direction is longer than a length of the first charge trap layer in the vertical direction.

17. The memory device according to claim 16, wherein the blocking layer extends to a space between the first and second charge trap layers and a space between the first and third charge trap layers.

18. The memory device according to claim 11, further comprising:
a gate line contacting a first side of the blocking layer.

19. The memory device according to claim 18, wherein the vertical length of the gate line is shorter than the vertical length of the blocking layer.
